(19) United States
(12) Patent Application Publication
(10) Pub. No.: US 2026/0136819 A1
(43) Pub. Date: May 14, 2026

(54) DISPLAY DEVICE AND ELECTRONIC DEVICE INCLUDING THE SAME

(71) Applicant: YouB LAB Inc., Seongnam-si (KR)

(72) Inventors: Bong Hyun YOU, Seoul (KR); Je In YOU, Seongnam-si (KR)

(21) Appl. No.: 19/428,354

(22) Filed: Dec. 22, 2025

Related U.S. Application Data
(63) Continuation of application No. PCT/KR2024/018170, filed on Nov. 18, 2024.

(30) Foreign Application Priority Data
Oct. 29, 2024 (KR) 10-2024-0149907

(51) Int. Cl. H10K 59/80; H10K 102/00

(52) U.S. Cl. CPC H10K 59/8794; H10K 2102/311

(57) ABSTRACT

A display device includes an elastic functional layer including an elastic material and a thermally conductive material, a support plate disposed over the elastic functional layer, a display panel disposed over the support plate, a circuit board disposed below the elastic functional layer, a first adhesive layer coupling the display panel and the support plate to each other, and a second adhesive layer coupling the elastic functional layer and the circuit board to each other and having a thermal conductivity greater than a thermal conductivity of the first adhesive layer.

### CROSS-REFERENCE TO RELATED APPLICATION

This application is a bypass continuation application of International Patent Application No. PCT/KR2024/018170, filed on November 18, 2024, which is based on and claims the benefit of priority to Korean Patent Application No. 10-2024-0149907, filed October 29, 2024, the disclosures of which are hereby incorporated by reference in their entireties.

### TECHNICAL FIELD

The present disclosure relates to a display device, and more specifically, to a flexible display device and an electronic device including the same.

### BACKGROUND

A display device is a device that displays an image to provide visual information to a user. A display device may include electronic components such as a display panel including a plurality of pixels emitting light, a circuit board for supplying electrical signals to the display panel, and a battery for supplying power to the display panel. While each of the plurality of pixels is driven, heat is generated in the circuit board and the electronic components, and such heat generation may cause problems in the operation of the display panel. Accordingly, a heat dissipation layer is disposed over the rear surface of the display panel to improve problems caused by such heat generation. Recently, a graphite sheet, which is a product obtained by thermally processing natural graphite, is generally used as a heat dissipation layer to increase thermal conductivity.

Meanwhile, in consideration of user convenience and portability, flexible display devices in which functions such as foldable, rollable, and stretchable are implemented are being developed. Since such a stretchable display device accompanies deformation of the display device during use, an elastic member having flexibility is disposed within the display device. Accordingly, there is a problem that the thickness of the display device increases when the heat dissipation layer and the elastic member are simultaneously disposed in the stretchable display device.

### SUMMARY

An object of the present disclosure is to provide a display device having improved heat dissipation efficiency.

Another object of the present disclosure is to provide an electronic device including the display device.

However, the objects of the present disclosure are not limited to the above-mentioned objects, and may be variously expanded without departing from the spirit and scope of the present disclosure.

To achieve the above object, a display device according to an embodiment of the present disclosure includes an elastic functional layer, a support plate, a display panel, a circuit board, a first adhesive layer, and a second adhesive layer. The elastic functional layer includes an elastic material and a thermally conductive material. The support plate is disposed over the elastic functional layer. The display panel is disposed over the support plate. The display panel includes a plurality of pixels. The circuit board is disposed below the elastic functional layer. The circuit board is electrically connected to the display panel. The first adhesive layer is disposed between the display panel and the support plate in a cross-sectional view. The first adhesive layer couples the display panel and the support plate to each other. The second adhesive layer is disposed between the elastic functional layer and the circuit board in a cross-sectional view. The second adhesive layer couples the elastic functional layer and the circuit board to each other. The second adhesive layer has a thermal conductivity greater than a thermal conductivity of the first adhesive layer.

In an embodiment, the thermally conductive material may include at least one selected from the group consisting of graphite powder, graphene, carbon fiber, carbon nano tube, and boron nitride (BN).

In an embodiment, the elastic material may include at least one selected from the group consisting of silicon (Si), polyurethane (PU), thermoplastic polyurethane (TPU), and polydimethylacrylamide (PDMA).

In an embodiment, a weight ratio of the thermally conductive material included in the elastic functional layer may be about 50 wt% or less.

In an embodiment, a thickness of the elastic functional layer may be about 10 μm to about 300 μm.

In an embodiment, a thermal conductivity of the elastic functional layer may be about 5 W/(m·K) to about 40 W/(m·K).

In an embodiment, the display panel may include a foldable area and a non-folding area adjacent to the foldable area. A width of the elastic functional layer may be constant from the non-folding area toward a center of the foldable area.

In an embodiment, the support plate may include a stretchable part and a flat part. The stretchable part may be disposed in the foldable area. The flat part may be disposed in the non-folding area. A plurality of lattice holes passing through the support plate in a thickness direction may be defined in the stretchable part.

In an embodiment, the elastic functional layer may overlap the entire stretchable part in a plan view.

To achieve the other object of the present disclosure, an electronic device according to an embodiment of the present disclosure includes a display panel, an elastic functional layer, a support plate, a circuit board, a first adhesive layer, a second adhesive layer, and a housing plate. The elastic functional layer includes an elastic material and a thermally conductive material. The support plate is disposed over the elastic functional layer. The display panel is disposed over the support plate. The display panel includes a plurality of pixels. The circuit board is disposed below the elastic functional layer. The circuit board is electrically connected to the display panel. The first adhesive layer is disposed between the display panel and the support plate in a cross-sectional view. The first adhesive layer couples the display panel and the support plate to each other. The second adhesive layer is disposed between the elastic functional layer and the circuit board in a cross-sectional view. The second adhesive layer couples the elastic functional layer and the circuit board to each other. The second adhesive layer has a thermal conductivity greater than a thermal conductivity of the first adhesive layer. The housing plate provides a space accommodating the display panel, the elastic functional layer, the support plate, and the circuit board.

In an embodiment, the thermally conductive material may include at least one selected from the group consisting of graphite powder, graphene, carbon fiber, carbon nano tube, and boron nitride (BN).

In an embodiment, the elastic material may include at least one selected from the group consisting of silicon (Si), polyurethane (PU), thermoplastic polyurethane (TPU), and polydimethylacrylamide (PDMA).

In an embodiment, a weight ratio of the thermally conductive material included in the elastic functional layer may be about 50 wt% or less.

In an embodiment, a thickness of the elastic functional layer may be about 10 μm to about 300 μm.

In an embodiment, a thermal conductivity of the elastic functional layer may be about 5 W/(m·K) to about 40 W/(m·K).

In an embodiment, the housing plate may include a housing and a hinge part. The housing may be disposed in the non-folding area and may accommodate the circuit board. The hinge part may be disposed in the foldable area and may protrude from one side surface of the housing plate toward an inside of the housing plate.

In an embodiment, the elastic functional layer may overlap the entire hinge part in a plan view.

In an embodiment, a width of the elastic functional layer may be constant from the non-folding area toward a center of the foldable area.

In an embodiment, the electronic device may further include a battery module. The battery module may be disposed in the non-folding area under the elastic functional layer. The battery module may supply power to the display panel. The second adhesive layer may couple the battery module and the elastic functional layer to each other.

To achieve the other object of the present disclosure, an electronic device according to an embodiment of the present disclosure includes a display panel, an elastic functional layer, a support plate, a circuit board, and a housing plate. The elastic functional layer includes an elastic material and a thermally conductive material. The support plate is disposed over the elastic functional layer. The display panel is disposed over the support plate. The display panel includes a plurality of pixels. The circuit board is disposed below the elastic functional layer. The circuit board is electrically connected to the display panel. The housing plate includes a housing and a hinge part. The housing is disposed in the non-folding area and accommodates the circuit board. The hinge part is disposed in the foldable area. The elastic functional layer overlaps the entire hinge part in a plan view. A width of the elastic functional layer is constant from the non-folding area toward a center of the foldable area.

According to embodiments of the present disclosure, in the electronic device, the thermal conductivity of the first adhesive layer coupling the support plate and the elastic functional layer to each other may be smaller than the thermal conductivity of the second adhesive layer coupling the elastic functional layer and the circuit board/electronic components to each other. Accordingly, heat emitted from each of the circuit board and the electronic components and transferred to the display panel can be effectively reduced. Therefore, the electronic device having improved heat dissipation efficiency and improved display quality can be provided.

In addition, the elastic functional layer may overlap the entire hinge part in a plan view, and the width of the elastic functional layer may be constant from the non-folding area toward the center of the foldable area. Accordingly, since an additional process of processing a graphite sheet included in a conventional electronic device such that its width decreases from the non-folding area toward the foldable area is not required, time and cost in the manufacturing process of the electronic device can be reduced. In addition, since the heat dissipation function and the elastic function are simultaneously performed by a single elastic functional layer, an electronic device having a relatively thin thickness can be easily manufactured.

However, the effects of the present disclosure are not limited to the above-mentioned effects, and may be variously expanded without departing from the spirit and scope of the present disclosure.

### BRIEF DESCRIPTION OF THE DRAWINGS

Embodiments will be more clearly understood from the following detailed description taken in conjunction with the accompanying drawings in which:

FIG. 1 is a perspective view illustrating an electronic device according to an embodiment of the present disclosure.

FIG. 2 is a perspective view illustrating a folded state of the electronic device of FIG. 1.

FIG. 3 is a block diagram illustrating a display device included in the electronic device of FIG. 1.

FIG. 4 is an exploded perspective view illustrating the electronic device of FIG. 1.

FIG. 5 is a cross-sectional view illustrating an example of a cross-section taken along line I-I' of FIG. 1.

FIG. 6 is a cross-sectional view illustrating a portion of the display module of FIG. 4.

FIG. 7 is a cross-sectional view illustrating another example of a cross-section taken along line I-I' of FIG. 1.

FIG. 8 is a cross-sectional view illustrating a portion of the housing plate of FIG. 4.

FIG. 9 is a cross-sectional view illustrating a folded state of the housing plate of FIG. 8.

FIG. 10 is a diagram for explaining a heat dissipation effect of the electronic device of FIG. 1.

FIG. 11 is an exploded perspective view illustrating a conventional electronic device.

FIG. 12 is a cross-sectional view illustrating a cross-section taken along line II-II' of FIG. 11.

FIG. 13A is a plan view illustrating the electronic device of FIG. 1

FIG. 13B is a plan view illustrating the conventional electronic device of FIG. 11.

FIG. 14 is a perspective view illustrating an electronic device according to another embodiment of the present disclosure.

FIG. 15 is a perspective view illustrating an expanded state of the electronic device of FIG. 14.

FIG. 16 is a cross-sectional view illustrating a cross-section of the electronic device of FIG. 14.

FIG. 17 is a cross-sectional view illustrating a cross-section of the expanded state of the electronic device of FIG. 14.

FIG. 18 is a block diagram illustrating the electronic devices of FIGS. 1 and 14.

### DETAILED DESCRIPTION

Embodiments of the present disclosure described herein are illustrated for the purpose of explaining the embodiments of the present disclosure, and the embodiments of the present disclosure may be implemented in various forms and should not be construed as limited to the embodiments set forth herein.

The present disclosure may be variously modified and may have various forms, and specific embodiments will be illustrated in the drawings and described in detail in the text.

However, this is not intended to limit the present disclosure to a specific disclosure form, and should be understood to include all modifications, equivalents, and substitutes included in the spirit and technical scope of the present disclosure.

Terms such as first, second, etc. may be used to describe various components, but the components should not be limited by the terms. The terms may be used for the purpose of distinguishing one component from another component. For example, without departing from the scope of the present disclosure, a first component may be referred to as a second component, and similarly, a second component may be referred to as a first component.

When a component is referred to as being “connected” or “coupled” to another component, it should be understood that it may be directly connected or coupled to the other component, but other components may exist therebetween. On the other hand, when a component is referred to as being “directly connected” or “directly coupled” to another component, it should be understood that no other component exists therebetween. Other expressions describing the relationship between components, such as “between” and “directly between” or “adjacent to” and “directly adjacent to,” should be interpreted similarly.

The terminology used herein is for the purpose of describing particular embodiments only and is not intended to be limiting of the present disclosure. Singular expressions include plural expressions unless the context clearly indicates otherwise. In the present application, terms such as “comprise,” “include,” or “have” are intended to designate that a feature, number, step, operation, component, part, or combination thereof described in the disclosure exists, but it should be understood that the existence or addition possibility of one or more other features, numbers, steps, operations, components, parts, or combinations thereof is not precluded in advance.

Unless otherwise defined, all terms used herein, including technical or scientific terms, have the same meaning as generally understood by those skilled in the art to which the present disclosure pertains. Terms such as those defined in generally used dictionaries should be interpreted as having meanings consistent with the meanings in the context of the related art, and are not interpreted in an ideal or excessively formal sense unless explicitly defined in the present application.

Meanwhile, when an embodiment can be implemented differently, a specific function or operation specified in a specific block may occur differently from the order specified in the flowchart. For example, two continuous blocks may actually be performed substantially simultaneously, or the blocks may be performed in reverse order depending on the related function or operation.

Hereinafter, preferred embodiments of the present disclosure will be described in more detail with reference to the accompanying drawings. The same reference numerals are used for the same components in the drawings, and duplicate descriptions of the same components are omitted.

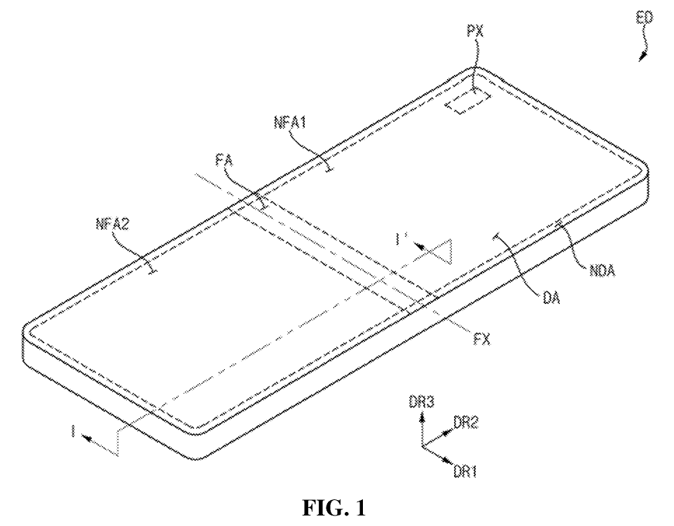

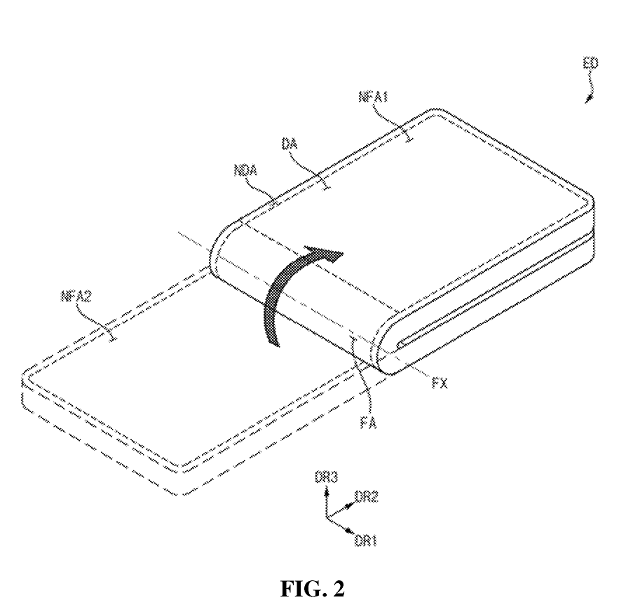

FIG. 1 is a perspective view illustrating an electronic device according to an embodiment of the present disclosure. FIG. 2 is a perspective view illustrating a folded state of the electronic device of FIG. 1. For example, FIG. 1 may be a perspective view illustrating a state in which an electronic device ED is unfolded.

Referring to FIGS. 1 and 2, the electronic device ED according to an embodiment of the present disclosure may include a display area DA and a non-display area NDA. In an embodiment, the electronic device ED may be a foldable electronic device.

In the present disclosure, a plane may be defined by a first direction DR1 and a second direction DR2 crossing the first direction DR1. For example, the first direction DR1 and the second direction DR2 may be perpendicular to each other. Also, a third direction DR3 may be perpendicular to the plane.

The display area DA may be an area capable of generating light to display an image. A plurality of pixels PX emitting light may be disposed in the display area DA, and accordingly, the image may be displayed in the display area DA. The plurality of pixels PX may be arranged in a matrix form along the first direction DR1 and the second direction DR2 crossing the first direction DR1.

The non-display area NDA may be an area that does not display an image. The non-display area NDA may be adjacent to the display area DA. In an embodiment, the non-display area NDA may surround at least a portion of the display area DA. For example, the non-display area NDA may entirely surround the display area DA.

In an embodiment, the electronic device ED may be a foldable electronic device. The electronic device ED may include a first non-folding area NFA1, a second non-folding area NFA2, and a foldable area FA depending on whether it is folded. For example, the first non-folding area NFA1 and the second non-folding area NFA2 may be spaced apart from each other, and the foldable area FA may be located between the first non-folding area NFA1 and the second non-folding area NFA2.

The foldable area FA is an area where the electronic device ED is folded along a folding axis FX parallel to the first direction DR1, and the first non-folding area NFA1 and the second non-folding area NFA2 may be areas where the electronic device ED is not folded. For example, the electronic device ED may be folded such that the first non-folding area NFA1 and the second non-folding area NFA2 face each other with respect to the foldable area FA. In addition, the foldable area FA may be folded to have a curvature. In the present disclosure, the first non-folding area NFA1 and the second non-folding area NFA2 may be referred to as non-folding areas.

However, the number of each of the foldable area FA and the non-folding areas included in the electronic device ED, the direction of the folding axis, the number of times of folding, etc. according to embodiments of the present disclosure are exemplary and are not necessarily limited thereto.

For example, in FIGS. 1 and 2, the electronic device ED is illustrated as including one foldable area FA and being folded once, but the electronic device ED may include two or more foldable areas and may include three or more non-folding areas. Also, the electronic device ED may be folded twice or more.

For example, in FIGS. 1 and 2, the foldable area FA extends in the first direction DR1 and the electronic device ED is folded in the second direction DR2 along the folding axis FX parallel to the first direction DR1, but the foldable area may extend in the second direction DR2 and the electronic device ED may be folded in the first direction DR1 along a folding axis parallel to the second direction DR2.

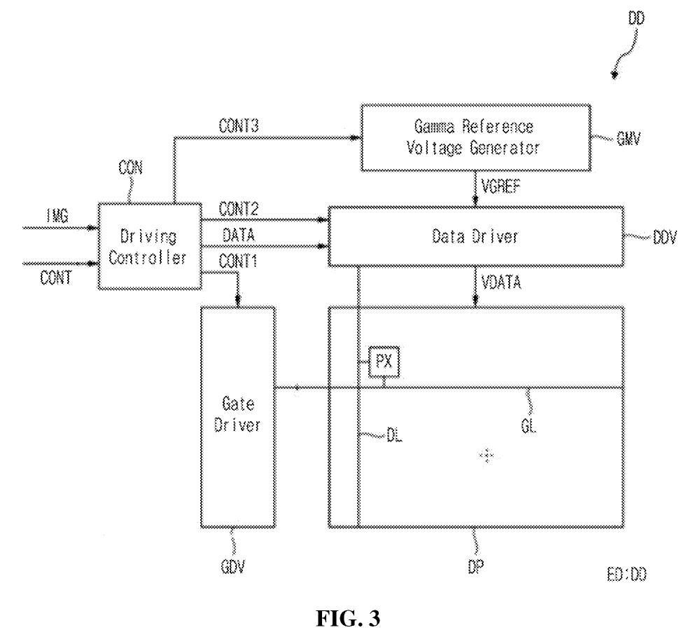

FIG. 3 is a block diagram illustrating a display device included in the electronic device of FIG. 1.

Referring to FIGS. 1 to 3, a display device DD included in the electronic device ED may include a display panel DP and a display panel driver. The display panel driver may include a driving controller CON, a gate driver GDV, a gamma reference voltage generator GMV, and a data driver DDV. Each of the driving controller CON, the gate driver GDV, the gamma reference voltage generator GMV, and the data driver DDV can be implemented as a circuit or circuitry.

Each of the display area DA and the non-display area NDA included in the electronic device ED may also be included in the display device DD. Also, each of the first non-folding area NFA1, the second non-folding area NFA2, and the foldable area FA included in the electronic device ED may also be included in the display device DD. For example, when the electronic device ED is folded, the display device DD may also be folded along the folding axis FX extending in the first direction DR1. Also, the display panel DP may include the first non-folding area NFA1, the second non-folding area NFA2, and the foldable area FA.

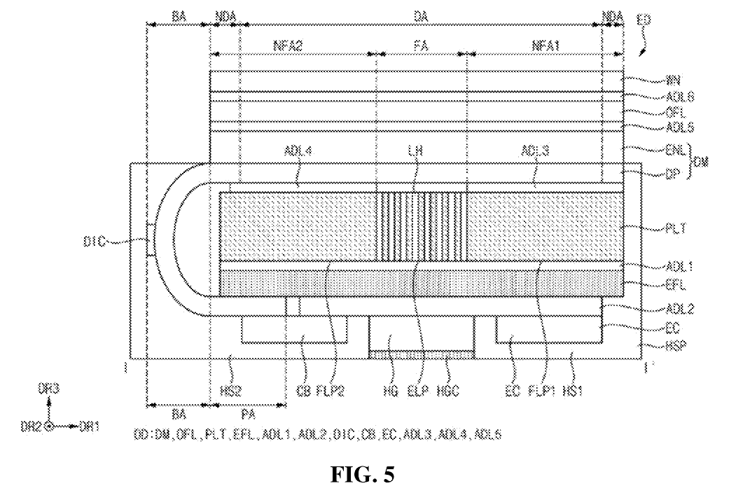

A plurality of pixels PX, a plurality of gate lines GL, and a plurality of data lines DL may be disposed in the display area DA of the display panel DP. The display panel driver may be disposed in areas other than the display area DA of the display panel DP (e.g., the non-display area NDA, a bending area (e.g., bending area BA of FIG. 5), and a pad area (e.g., pad area PA of FIG. 5)).

One pixel among the plurality of pixels PX may include sub-pixels emitting light of different colors. For example, one pixel may include a first sub-pixel emitting light of a first color, a second sub-pixel emitting light of a second color, and a third sub-pixel emitting light of a third color.

In an embodiment, the first color light may be red light, the second color light may be green light, and the third color light may be blue light. However, the color of light emitted by each of the first sub-pixel, the second sub-pixel, and the third sub-pixel according to embodiments of the present disclosure is not necessarily limited thereto. For example, each of the first sub-pixel, the second sub-pixel, and the third sub-pixel may be combined to emit magenta light, cyan light, and yellow light.

In an embodiment, the plurality of gate lines GL may extend along one direction. In an embodiment, the plurality of data lines DL may extend along one direction. In an embodiment, each of the plurality of gate lines GL may be spaced apart in a plan view. In an embodiment, each of the plurality of data lines DL may be spaced apart in a plan view.

In an embodiment, the plurality of gate lines GL and the plurality of data lines DL may cross each other in a plan view. For example, the plurality of gate lines GL and the plurality of data lines DL may be orthogonal to each other in a plan view.

The driving controller CON may receive input image data IMG and an input control signal CONT from an external device (e.g., a processor such as a graphic processing unit (GPU)). In an embodiment, the driving controller CON, the gamma reference voltage generator GMV, and the data driver DDV may be integrally formed. For example, a module in which the driving controller CON and the data driver DDV are integrally formed may be referred to as a timing controller embedded data driver (TED).

In an embodiment, the input image data IMG may include red image data, green image data, and blue image data. In an embodiment, the input image data IMG may further include white image data. In another embodiment, the input image data IMG may include magenta image data, yellow image data, and cyan image data.

In an embodiment, the input control signal CONT may include a master clock signal and a data enable signal. In an embodiment, the input control signal CONT may further include a vertical synchronization signal and a horizontal synchronization signal.

The driving controller CON may generate a gate control signal CONT1 for controlling the operation of the gate driver GDV based on the input control signal CONT. The driving controller CON may output the gate control signal CONT1 to the gate driver GDV. The gate control signal CONT1 may include a vertical start signal and a gate clock signal.

The driving controller CON may generate a data control signal CONT2 for controlling the operation of the data driver DDV based on the input control signal CONT. The driving controller CON may output the data control signal CONT2 to the data driver DDV. The data control signal CONT2 may include a horizontal start signal and a load signal.

The driving controller CON may generate a data signal DATA based on the input image data IMG. Accordingly, the driving controller CON may output the data signal DATA to the data driver DDV through the plurality of data lines DL.

The driving controller CON may generate a gamma control signal CONT3 for controlling the operation of the gamma reference voltage generator GMV based on the input control signal CONT. The driving controller CON may output the gamma control signal CONT3 to the gamma reference voltage generator GMV.

The gate driver GDV may generate output signals for driving the plurality of gate lines GL in response to the gate control signal CONT1 input from the driving controller CON. In an embodiment, the gate driver GDV may be included in the display panel DP. For example, the gate driver GDV may be integrated in the non-display area NDA of the display panel DP, so that the display device DD may have a Gate-in-Panel (GIP) structure in which the display panel DP and the gate driver GDV are integrally formed with each other. However, the gate driver GDV according to embodiments of the present disclosure is not necessarily limited thereto, and the gate driver GDV may be provided in the display device DD separately from the display panel DP.

The gamma reference voltage generator GMV may generate a gamma reference voltage VGREF in response to the gamma control signal CONT3 input from the driving controller CON. The gamma reference voltage generator GMV may provide the gamma reference voltage VGREF to the data driver DDV.

The data driver DDV may receive the data control signal CONT2 and the data signal DATA from the driving controller CON. The data driver DDV may receive the gamma reference voltage VGREF from the gamma reference voltage generator GMV. The data driver DDV may convert the data signal DATA into an analog data voltage VDATA using the gamma reference voltage VGREF. The data driver DDV may output the data voltage VDATA to each of the plurality of data lines DL.

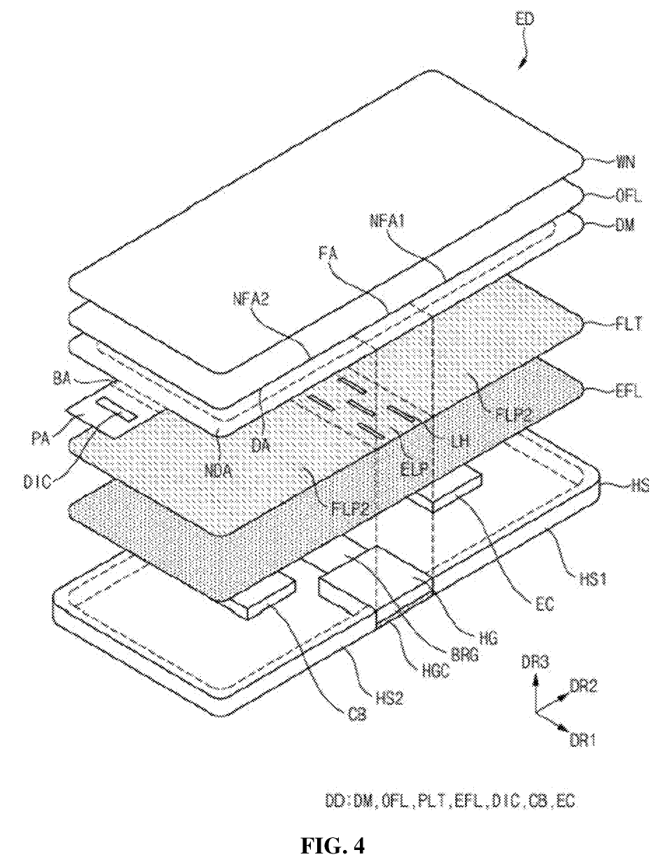

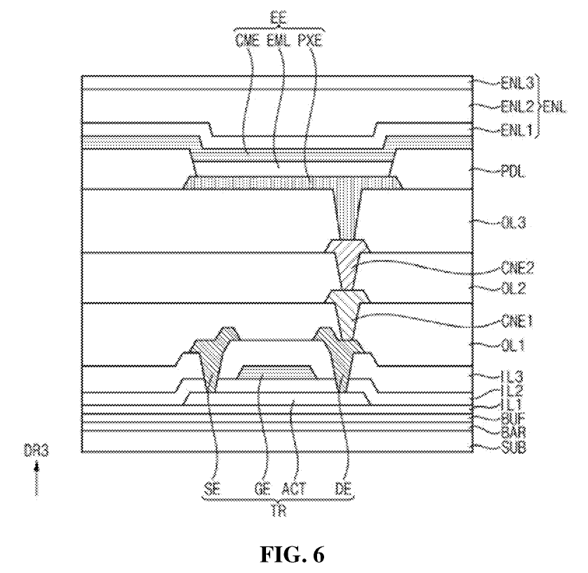

FIG. 4 is an exploded perspective view illustrating the electronic device of FIG. 1. FIG. 5 is a cross-sectional view illustrating an example of a cross-section taken along line I-I' of FIG. 1. FIG. 6 is a cross-sectional view illustrating a portion of the display module of FIG. 4.

Referring to FIGS. 4 to 6, the electronic device ED may include a display module DM, a support plate PLT, a first adhesive layer ADL1, an elastic functional layer EFL, a second adhesive layer ADL2, a circuit board CB, a driving chip DIC, an electronic component EC, a third adhesive layer ADL3, a fourth adhesive layer ADL4, a fifth adhesive layer ADL5, an optical functional layer OFL, a sixth adhesive layer ADL6, a cover window WN, and a housing plate HSP.

The display module DM may include a display panel DP and an encapsulation layer ENL. The display module DM, the support plate PLT, the first adhesive layer ADL1, the elastic functional layer EFL, the second adhesive layer ADL2, the circuit board CB, the driving chip DIC, the electronic component EC, the third adhesive layer ADL3, the fourth adhesive layer ADL4, the fifth adhesive layer ADL5, and the optical functional layer OFL may define the display device DD.

The display panel DP may include a substrate SUB, a barrier layer BAR, a buffer layer BUF, a first insulating layer IL1, an active layer ACT, a second insulating layer IL2, a gate electrode GE, a third insulating layer IL3, a source electrode SE, a drain electrode DE, a first organic insulating layer OL1, a first connection electrode CNE1, a second organic insulating layer OL2, a second connection electrode CNE2, a third organic insulating layer OL3, a pixel electrode PXE, a pixel defining layer PDL, a light emitting layer EML, and a common electrode CME. The encapsulation layer ENL may include a first encapsulation layer ENL1, a second encapsulation layer ENL2, and a third encapsulation layer ENL3.

The active layer ACT, the gate electrode GE, the source electrode SE, and the drain electrode DE may define a transistor TR. The pixel electrode PXE, the light emitting layer EML, and the common electrode CME may define a light emitting element EE.

The display module DM may be disposed across the first non-folding area NFA1, the second non-folding area NFA2, and the foldable area FA. The display panel DP may further include a bending area BA adjacent to the non-display area NDA, and a pad area PA adjacent to the bending area BA. A portion of the display panel DP located in the bending area BA may be bent toward a lower portion of the support plate PLT. A portion of the display panel DP located in the pad area PA may extend in the first direction DR1 and the second direction DR2 at the lower portion of the support plate PLT.

The substrate SUB may serve as a base of the display panel DP. The substrate SUB may be formed of a transparent or opaque material. The substrate SUB may be formed of glass, quartz, plastic, or the like. For example, the plastic may include polyimide, polyethylene naphthalate, polyethylene terephthalate, polycarbonate, polyetherimide, polyethersulfone, and the like. These may be used alone or in combination with each other.

The barrier layer BAR may be disposed on the substrate SUB. The barrier layer BAR may reduce moisture permeability of the substrate SUB and prevent foreign substances from diffusing into the light emitting element EE. The barrier layer BAR may include amorphous silicon, silicon oxide, silicon nitride, and the like. These may be used alone or in combination with each other.

In FIG. 6, each of the substrate SUB and the barrier layer BAR is illustrated as having a single-layer structure, but embodiments of the present disclosure are not limited thereto, and each of the substrate SUB and the barrier layer BAR may have a multi-layer structure. Also, a structure in which a plurality of layers included in the substrate SUB and a plurality of layers included in the barrier layer BAR are alternately stacked may be provided.

The buffer layer BUF may be disposed on the barrier layer BAR. The buffer layer BUF may prevent diffusion of metal atoms or impurities from the substrate SUB into the active layer ACT. Also, the buffer layer BUF may control a heat transfer rate during a crystallization process for forming the active layer ACT.

The first insulating layer IL1 may be disposed on the buffer layer BUF. The first insulating layer IL1 may include an inorganic insulating material. The inorganic insulating material may include silicon nitride (SiNx), silicon oxide (SiOx), silicon oxynitride (SiOxNy), and the like. These may be used alone or in combination with each other.

The active layer ACT may be disposed on the first insulating layer IL1. The active layer ACT may include amorphous silicon, polycrystalline silicon, or an oxide semiconductor. The active layer ACT may include a source region and a drain region doped with impurities, and a channel region disposed between the source region and the drain region.

The second insulating layer IL2 may be disposed on the first insulating layer IL1. The second insulating layer IL2 may cover the active layer ACT on the first insulating layer IL1. For example, the second insulating layer IL2 may have a substantially uniform thickness along the profile of the active layer ACT. However, the second insulating layer IL2 according to embodiments of the present disclosure is not necessarily limited thereto, and the second insulating layer IL2 may sufficiently cover the active layer ACT and have a substantially flat top surface without creating a step around the active layer ACT.

In an embodiment, the second insulating layer IL2 may include an inorganic insulating material. The inorganic insulating material may include silicon nitride, silicon oxide, silicon oxynitride, and the like. These may be used alone or in combination with each other.

The gate electrode GE may be disposed on the second insulating layer IL2. The gate electrode GE may overlap the channel region of the active layer ACT in a plan view. The gate electrode GE may include a metal, an alloy, a conductive metal oxide, a conductive metal nitride, a transparent conductive material, and the like.

The third insulating layer IL3 may be disposed on the second insulating layer IL2. The third insulating layer IL3 may cover the gate electrode GE on the second insulating layer IL2. For example, the third insulating layer IL3 may have a substantially uniform thickness along the profile of the gate electrode GE. However, the third insulating layer IL3 according to embodiments of the present disclosure is not necessarily limited thereto, and the third insulating layer IL3 may sufficiently cover the gate electrode GE and have a substantially flat top surface without creating a step around the gate electrode GE.

In an embodiment, the third insulating layer IL3 may include an inorganic insulating material. The inorganic insulating material may include silicon nitride, silicon oxide, silicon oxynitride, and the like. These may be used alone or in combination with each other.

The source electrode SE and the drain electrode DE may be disposed on the third insulating layer IL3. The source electrode SE and the drain electrode DE may contact the active layer ACT through contact holes passing through the second insulating layer IL2 and the third insulating layer IL3. For example, the source electrode SE may contact the source region of the active layer ACT, and the drain electrode DE may contact the drain region of the active layer ACT. In an embodiment, each of the source electrode SE and the drain electrode DE may include a metal, an alloy, a conductive metal oxide, a conductive metal nitride, a transparent conductive material, and the like.

The first organic insulating layer OL1 may be disposed on the third insulating layer IL3. For example, the first organic insulating layer OL1 may cover the source electrode SE and the drain electrode DE on the third insulating layer IL3. In an embodiment, the first organic insulating layer OL1 may have a substantially flat top surface.

In an embodiment, a hole through which a portion of the top surface of the drain electrode DE is exposed may be defined in the first organic insulating layer OL1. However, the first organic insulating layer OL1 according to embodiments of the present disclosure is not necessarily limited thereto, and a hole through which a portion of the top surface of the source electrode SE is exposed may be defined in the first organic insulating layer OL1.

In an embodiment, the first organic insulating layer OL1 may include an organic insulating material. For example, the organic insulating material may include acrylic resin, epoxy resin, polyimide, polyethylene, and the like. These may be used alone or in combination with each other.

The first connection electrode CNE1 may be disposed on the first organic insulating layer OL1. In an embodiment, the first connection electrode CNE1 may contact the drain electrode DE through the hole exposing the top surface of the drain electrode DE. In another embodiment, the first connection electrode CNE1 may contact the source electrode SE through the hole exposing the top surface of the source electrode SE. In an embodiment, the first connection electrode CNE1 may include a metal, an alloy, a conductive metal oxide, a conductive metal nitride, a transparent conductive material, and the like.

The second organic insulating layer OL2 may be disposed on the first organic insulating layer OL1. For example, the second organic insulating layer OL2 may cover the first connection electrode CNE1 on the first organic insulating layer OL1. The second organic insulating layer OL2 may have a substantially flat top surface. A hole through which a portion of the top surface of the first connection electrode CNE1 is exposed may be defined in the second organic insulating layer OL2.

In an embodiment, the second organic insulating layer OL2 may include an organic insulating material. For example, the organic insulating material may include acrylic resin, epoxy resin, polyimide, polyethylene, and the like. These may be used alone or in combination with each other.

The second connection electrode CNE2 may be disposed on the second organic insulating layer OL2. The second connection electrode CNE2 may contact the first connection electrode CNE1 through the hole defined in the second organic insulating layer OL2. The second connection electrode CNE2 may include a metal, an alloy, a conductive metal oxide, a conductive metal nitride, a transparent conductive material, and the like.

In an embodiment, the first connection electrode CNE1 and the second connection electrode CNE2 may physically and/or electrically connect the drain electrode DE and the pixel electrode PXE. However, the first connection electrode CNE1 and the second connection electrode CNE2 according to embodiments of the present disclosure are not necessarily limited thereto, and the first connection electrode CNE1 and the second connection electrode CNE2 may physically and/or electrically connect the source electrode SE and the pixel electrode PXE. Also, although the display panel DP is illustrated as including two connection electrodes in FIG. 6, the display panel DP in embodiments of the present disclosure is not necessarily limited thereto. For example, the display panel DP may include one or less or three or more connection electrodes.

The third organic insulating layer OL3 may be disposed on the second organic insulating layer OL2. The third organic insulating layer OL3 may cover the second connection electrode CNE2 on the second organic insulating layer OL2. In an embodiment, the third organic insulating layer OL3 may have a substantially flat top surface. A hole through which a portion of the top surface of the second connection electrode CNE2 is exposed may be defined in the third organic insulating layer OL3.

In an embodiment, the third organic insulating layer OL3 may include an organic insulating material. For example, the organic insulating material may include acrylic resin, epoxy resin, polyimide, polyethylene, and the like. These may be used alone or in combination with each other.

The pixel electrode PXE may be disposed on the third organic insulating layer OL3. In an embodiment, the pixel electrode PXE may contact the second connection electrode CNE2 through the hole defined in the third organic insulating layer OL3. In an embodiment, the pixel electrode PXE may include a metal, an alloy, a conductive metal oxide, a conductive metal nitride, a transparent conductive material, and the like. These may be used alone or in combination with each other. For example, the pixel electrode PXE may include silver (Ag) and indium tin oxide (ITO).

The pixel defining layer PDL may be disposed on the third organic insulating layer OL3. The pixel defining layer PDL may partially cover the pixel electrode PXE. Also, a hole exposing at least a portion of the pixel electrode PXE may be defined in the pixel defining layer PDL. For example, the hole of the pixel defining layer PDL may expose a central portion of the pixel electrode PXE, and the pixel defining layer PDL may cover an edge of the pixel electrode PXE. The pixel defining layer PDL may include an organic insulating material such as polyimide.

In an embodiment, the pixel defining layer PDL may further include a light blocking material. The light blocking material may include carbon black, carbon nanotubes, a resin or paste containing black dye, metal particles, and the like. The metal particles may include nickel (Ni), aluminum (Al), molybdenum (Mo), chromium (Cr), and the like. These may be used alone or in combination with each other. When the pixel defining layer PDL includes the light blocking material, external light reflection by metal structures (e.g., the pixel electrode PXE, etc.) disposed below the pixel defining layer PDL can be reduced.

The light emitting layer EML may be disposed on the pixel electrode PXE. For example, the light emitting layer EML may be disposed on the pixel electrode PXE exposed by the hole of the pixel defining layer PDL. The light emitting layer EML may include an organic light emitting material. The organic light emitting material may include a low molecular weight organic compound or a high molecular weight organic compound. However, the present disclosure is not limited thereto, and the light emitting layer EML may include a material such as quantum dots.

The common electrode CME may be disposed on the light emitting layer EML. For example, the common electrode CME may cover the light emitting layer EML and the pixel defining layer PDL. In an embodiment, the common electrode CME may include a metal, an alloy, a conductive metal oxide, a conductive metal nitride, a transparent conductive material, and the like. For example, the common electrode CME may include aluminum, platinum (Pt), silver, magnesium (Mg), gold (Au), chromium, tungsten (W), titanium (Ti), and the like. These may be used alone or in combination with each other.

The first encapsulation layer ENL1 may be disposed on the common electrode CME. The first encapsulation layer ENL1 may cover the light emitting element EE. The first encapsulation layer ENL1 may have a substantially uniform thickness along the profile of the common electrode CME. The first encapsulation layer ENL1 may include an inorganic insulating material. For example, the inorganic insulating material may include silicon nitride, silicon oxide, silicon oxynitride, and the like. These may be used alone or in combination with each other.

The second encapsulation layer ENL2 may be disposed on the first encapsulation layer ENL1. The second encapsulation layer ENL2 may have a substantially flat top surface without creating a step around the first encapsulation layer ENL1. The second encapsulation layer ENL2 may include an organic insulating material. For example, the organic insulating material may include acrylic resin, epoxy resin, polyimide, polyethylene, and the like. These may be used alone or in combination with each other.

The third encapsulation layer ENL3 may be disposed on the second encapsulation layer ENL2. The third encapsulation layer ENL3 may have a substantially uniform thickness and a substantially flat top surface. The third encapsulation layer ENL3 may include an inorganic insulating material. For example, the inorganic insulating material may include silicon nitride, silicon oxide, silicon oxynitride, and the like. These may be used alone or in combination with each other. The encapsulation layer ENL may seal the display area DA to protect the light emitting element EE from external impurities.

In an embodiment, the encapsulation layer ENL including the first encapsulation layer ENL1, the second encapsulation layer ENL2, and the third encapsulation layer ENL3 may be a thin film encapsulation layer. However, the structure of the encapsulation layer ENL according to embodiments of the present disclosure is not necessarily limited thereto, and the encapsulation layer ENL may have a single-layer structure or the encapsulation layer ENL may be a glass substrate.

The support plate PLT may be disposed below the display panel DP. For example, the support plate PLT may be disposed across the first non-folding area NFA1, the second non-folding area NFA2, and the foldable area FA under the display panel DP. The support plate PLT may support the display panel DP to supplement the rigidity of the electronic device ED. In an embodiment, the support plate PLT may include a metal material. For example, the metal material may include stainless steel (SUS), aluminum, and the like. These may be used alone or in combination with each other.

In an embodiment, the support plate PLT may include a polymer material. For example, the polymer material may include polymethylmethacrylate (PMMA), polycarbonate (PC), polyvinyl alcohol (PVA), acrylonitrile-butadiene-styrene (ABS), polyethylene terephthalate (PET), glass fiber reinforced plastic (GFRP), carbon fiber reinforced plastic (CFRP), and the like. These may be used alone or in combination with each other.

The support plate PLT may include a first flat part FLP1, a second flat part FLP2, and a stretchable part ELP. The first flat part FLP1 may be disposed in the first non-folding area NFA1, and the second flat part FLP2 may be disposed in the second non-folding area NFA2. The stretchable part ELP may be disposed in the foldable area FA. In the present disclosure, the first flat part FLP1 and the second flat part FLP2 may be referred to as flat parts. In an embodiment, a thickness of the support plate PLT may be about 0.1 mm to about 0.25 mm.

A plurality of lattice holes LH penetrating the support plate PLT in a thickness direction (e.g., the third direction DR3) may be defined in the stretchable part ELP. The stretchable part ELP may be folded through the plurality of lattice holes LH. In an embodiment, the plurality of lattice holes LH may be repeatedly arranged with a specific pattern in the first direction DR1 and the second direction DR2 within the foldable area FA. The stretchable part ELP may have a lattice pattern that has a specific rule and repeats by the arrangement of the plurality of lattice holes LH. However, the stretchable part ELP according to embodiments of the present disclosure is not necessarily limited thereto, and the plurality of lattice holes LH may not be defined in the stretchable part ELP.

The elastic functional layer EFL may be disposed below the support plate PLT. For example, the elastic functional layer EFL may be disposed across the first non-folding area NFA1, the second non-folding area NFA2, and the foldable area FA at the lower portion of the support plate PLT. In an embodiment, the elastic functional layer EFL may overlap the entire stretchable part ELP in a plan view. For example, the elastic functional layer EFL may overlap the entire plurality of lattice holes LH in a plan view.

In an embodiment, a width of the elastic functional layer EFL (e.g., a length in the first direction DR1) may be constant from the first non-folding area NFA1 or the second non-folding area NFA2 toward the center of the foldable area FA. Specifically, the length in the first direction DR1 of the portion of the elastic functional layer EFL located in the foldable area FA may be substantially the same as the length in the first direction DR1 of the portion of the elastic functional layer EFL located in the first non-folding area NFA1 or the second non-folding area NFA2. In an embodiment, the elastic functional layer EFL may have a rectangular planar shape. However, the planar shape of the elastic functional layer EFL according to embodiments of the present disclosure is not necessarily limited thereto.

In an embodiment, while the electronic device ED repeatedly performs folding and unfolding, the elastic functional layer EFL may prevent foreign substances from penetrating into the stretchable part ELP. Also, while the electronic device ED repeatedly performs folding and unfolding, the elastic functional layer EFL may repeatedly stretch and contract so that the stretchable part ELP is not exposed.

In an embodiment, the elastic functional layer EFL may perform a heat dissipation function of heat emitted from each of the circuit board CB and the electronic component EC. Specifically, the elastic functional layer EFL may evenly distribute heat emitted from each of the circuit board CB and the electronic component EC in the first direction DR1 and the second direction DR2.

In an embodiment, the elastic functional layer EFL may include an elastic material having a relatively large elastic force or a relatively large restoring force and a thermally conductive material. For example, the elastic material may include silicon (Si), polyurethane (PU), thermoplastic polyurethane (TPU), polydimethylacrylamide (PDMA), and the like. These may be used alone or in combination with each other. Also, the thermally conductive material may include graphite powder, graphene, carbon fiber, carbon nano tube, boron nitride (BN), and the like. These may be used alone or in combination with each other.

In an embodiment, a weight ratio of the thermally conductive material included in the elastic functional layer EFL may be about 50 wt% or less. Preferably, the weight ratio of the thermally conductive material included in the elastic functional layer EFL may be about 10 wt% or more and about 50 wt% or less. If the weight ratio of the thermally conductive material exceeds 50 wt%, stretching and contraction of the elastic functional layer EFL may not be easy.

In an embodiment, a thermal conductivity of the elastic functional layer EFL may be about 5 W/(m·K) to about 40 W/(m·K). Preferably, the thermal conductivity of the elastic functional layer EFL may be about 5 W/(m·K) to about 30 W/(m·K). More preferably, the thermal conductivity of the elastic functional layer EFL may be about 6 W/(m·K) to about 20 W/(m·K).

In an embodiment, a thickness of the elastic functional layer EFL may be about 10 μm to about 300 μm. Preferably, the thickness of the elastic functional layer EFL may be about 150 μm to about 250 μm. More preferably, the thickness of the elastic functional layer EFL may be about 160 μm to about 200 μm.

The first adhesive layer ADL1 may be disposed between the support plate PLT and the elastic functional layer EFL in a cross-sectional view. The first adhesive layer ADL1 may couple the support plate PLT and the elastic functional layer EFL to each other. In an embodiment, the first adhesive layer ADL1 may be a pressure sensitive adhesive (PSA), a PET tape, or the like.

In an embodiment, the first adhesive layer ADL1 may be disposed across the first non-folding area NFA1, the second non-folding area NFA2, and the foldable area FA. However, the arrangement and type of the first adhesive layer ADL1 according to embodiments of the present disclosure are not necessarily limited thereto. For example, the first adhesive layer ADL1 may be disposed only in the first non-folding area NFA1 and the second non-folding area NFA2 to couple the support plate PLT and the elastic functional layer EFL to each other.

The circuit board CB may be disposed below the elastic functional layer EFL. For example, the circuit board CB may be disposed in the pad area PA on the display panel DP. Specifically, the circuit board CB may be disposed on a portion where the display panel DP is bent and extends to the lower portion of the elastic functional layer EFL. In an embodiment, the circuit board CB may be a printed circuit board (PCB).

The circuit board CB may overlap a portion of the display panel DP located in the pad area PA in a plan view. The circuit board CB may be electrically connected to the display panel DP. For example, the circuit board CB and the display panel DP may be electrically connected to each other through pad electrodes overlapping simultaneously with the circuit board CB and the display panel DP in a plan view. In an embodiment, the circuit board CB may be disposed in the second non-folding area NFA2. However, the arrangement of the circuit board CB according to embodiments of the present disclosure is not necessarily limited thereto.

The driving chip DIC may be located in the bending area BA. For example, the driving chip DIC may be disposed on the display panel DP in the bending area BA. Specifically, the driving chip DIC may have a chip on panel (COP) structure mounted on the display panel DP. However, the mounting structure of the driving chip DIC according to embodiments of the present disclosure is exemplary and is not necessarily limited thereto.

At least a portion of the display panel driver for driving the display panel DP may be formed as the driving chip DIC in the form of a chip. In an embodiment, the driving chip DIC may include the data driver DDV of FIG. 3. In an embodiment, the driving chip DIC may include the data driver DDV and the gamma reference voltage generator GMV of FIG. 3. In an embodiment, the driving chip DIC may include the driving controller CON, the data driver DDV, and the gamma reference voltage generator GMV of FIG. 3. However, the driving chip DIC according to embodiments of the present disclosure is not necessarily limited thereto.

The electronic component EC may be disposed below the elastic functional layer EFL. For example, the electronic component EC may be disposed in the first non-folding area NFA1 below the elastic functional layer EFL. The electronic component EC may include a battery module for supplying power to the electronic device ED. However, the arrangement and type of the electronic component EC according to embodiments of the present disclosure are not necessarily limited thereto.

The second adhesive layer ADL2 may be disposed between the elastic functional layer EFL and the circuit board CB and electronic component EC in a cross-sectional view. The second adhesive layer ADL2 may couple the elastic functional layer EFL to the circuit board CB and the electronic component EC. In an embodiment, the second adhesive layer ADL2 may be a pressure sensitive adhesive (PSA), a PET tape, or the like. However, the coupling relationship of each of the circuit board CB and the electronic component EC according to embodiments of the present disclosure is not necessarily limited thereto, and an adhesive layer coupling the circuit board CB and the elastic functional layer EFL and an adhesive layer coupling the electronic component EC may be separate components spaced apart from each other in a plan view.

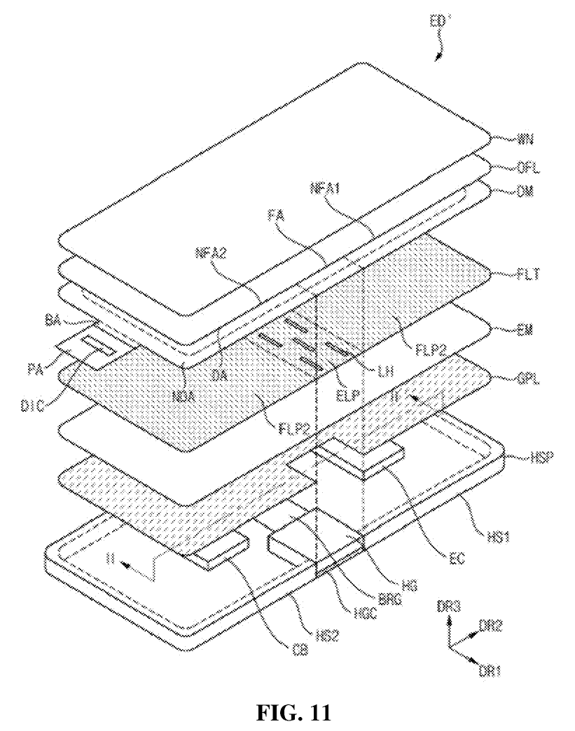

In an embodiment, the second adhesive layer ADL2 may be disposed across the first non-folding area NFA1, the second non-folding area NFA2, and the foldable area FA. However, the arrangement and type of the second adhesive layer ADL2 according to embodiments of the present disclosure are not necessarily limited thereto. In an embodiment, the thermal conductivity of the first adhesive layer ADL1 may be smaller than the thermal conductivity of the second adhesive layer ADL2. This will be described later with reference to FIG. 10.

The third adhesive layer ADL3 may be disposed in the first non-folding area NFA1. The third adhesive layer ADL3 may be disposed between the support plate PLT and the display panel DP in a cross-sectional view. The third adhesive layer ADL3 may couple the support plate PLT and the display panel DP to each other. In an embodiment, the third adhesive layer ADL3 may be a pressure sensitive adhesive (PSA), a PET tape, or the like. However, the arrangement and type of the third adhesive layer ADL3 according to embodiments of the present disclosure are not necessarily limited thereto.

The fourth adhesive layer ADL4 may be disposed in the second non-folding area NFA2. The fourth adhesive layer ADL4 may be disposed between the support plate PLT and the display panel DP in a cross-sectional view. The fourth adhesive layer ADL4 may couple the support plate PLT and the display panel DP to each other. In an embodiment, the fourth adhesive layer ADL4 may be a pressure sensitive adhesive (PSA), a PET tape, or the like. However, the arrangement and type of the fourth adhesive layer ADL4 according to embodiments of the present disclosure are not necessarily limited thereto.

In an embodiment, the third adhesive layer ADL3 and the fourth adhesive layer ADL4 may be integrally formed. However, the relationship between the third adhesive layer ADL3 and the fourth adhesive layer ADL4 according to embodiments of the present disclosure is not necessarily limited thereto.

The optical functional layer OFL may be disposed over the encapsulation layer ENL. For example, the optical functional layer OFL may be disposed across the first non-folding area NFA1, the second non-folding area NFA2, and the foldable area FA on the encapsulation layer ENL.

The optical functional layer OFL may control external light incident on the display panel DP. In an embodiment, the optical functional layer OFL may be a polarizing layer. The polarizing layer may stretch in one direction. The direction in which the polarizing layer stretches may be an absorption axis absorbing light, and a direction perpendicular to the stretching direction may be a transmission axis transmitting light. However, the optical functional layer OFL according to embodiments of the present disclosure is not limited to a polarizing layer, and the electronic device ED may have a structure that does not include a polarizing layer. When the electronic device ED does not include a polarizing layer, the optical functional layer OFL may be a color filter or the like.

The fifth adhesive layer ADL5 may be disposed across the first non-folding area NFA1, the second non-folding area NFA2, and the foldable area FA. The fifth adhesive layer ADL5 may be disposed between the encapsulation layer ENL and the optical functional layer OFL in a cross-sectional view. The fifth adhesive layer ADL5 may couple the encapsulation layer ENL and the optical functional layer OFL to each other. In an embodiment, the fifth adhesive layer ADL5 may be a pressure sensitive adhesive (PSA), a PET tape, an optical clear resin (OCR), an optical clear adhesive (OCA), or the like.

The cover window WN may be disposed over the optical functional layer OFL. For example, the cover window WN may be disposed across the first non-folding area NFA1, the second non-folding area NFA2, and the foldable area FA on the optical functional layer OFL. The cover window WN may perform a role of protecting the screen of the electronic device ED.

In an embodiment, the cover window WN may be ultra-thin glass. For example, the cover window WN may include soda lime glass, alkali aluminosilicate glass, borosilicate glass, lithium alumina silicate glass, and the like. These may be used alone or in combination with each other. However, the cover window WN of the present disclosure is not limited thereto and may include various materials such as plastic.

The sixth adhesive layer ADL6 may be disposed across the first non-folding area NFA1, the second non-folding area NFA2, and the foldable area FA. The sixth adhesive layer ADL6 may be disposed between the optical functional layer OFL and the cover window WN in a cross-sectional view. The sixth adhesive layer ADL6 may couple the optical functional layer OFL and the cover window WN to each other. In an embodiment, the sixth adhesive layer ADL6 may be a pressure sensitive adhesive (PSA), a PET tape, an optical clear resin (OCR), an optical clear adhesive (OCA), or the like.

The housing plate HSP may accommodate at least a portion of the display device DD. For example, the housing plate HSP may provide a space accommodating the circuit board CB, the electronic component EC, the elastic functional layer EFL, the support plate PLT, and the display panel DP. However, the accommodation range of the housing plate HSP according to embodiments of the present disclosure is not necessarily limited thereto.

The housing plate HSP may include a first housing HS1, a second housing HS2, a hinge part HG, a hinge cover HGC, and a bridge structure BRG. The first housing HS1 may provide an accommodation space for the electronic component EC. The first housing HS1 may be disposed corresponding to the first non-folding area NFA1. The second housing HS2 may provide an accommodation space for the circuit board CB. The second housing HS2 may be disposed corresponding to the second non-folding area NFA2. In the present disclosure, the first housing HS1 and the second housing HS2 may be referred to as a housing.

In an embodiment, the hinge part HG may be disposed corresponding to the foldable area FA. Specifically, the hinge part HG may be located at a central portion of each of both side surfaces of the housing plate HSP parallel to the first direction DR1. While the electronic device ED repeatedly performs folding and unfolding, the hinge part HG may rotate and/or move. The hinge part HG may protrude inward from a side parallel to the second direction DR2 of the housing plate HSP.

The hinge cover HGC may cover a surface of the hinge part HG facing outward. The hinge cover HGC may be disposed between the first housing HS1 and the second housing HS2. For example, the hinge cover HGC may hide the hinge part HG between the first housing HS1 and the second housing HS2. In an embodiment, the hinge cover HGC may have a curved surface.

The bridge structure BRG may be connected to the hinge part HG. For example, the bridge structure BRG may be coupled to the hinge part HG to define a hinge assembly assisting the housing plate HSP to perform a folding or unfolding operation. The bridge structure BRG may extend along the first direction DR1. Specifically, the bridge structure BRG may couple two hinge parts located on both side surfaces of the housing plate HSP parallel to the first direction DR1 to each other. In an embodiment, the hinge part HG and the bridge structure BRG may be coupled to each other and then coupled to each of the first housing HS1 and second housing HS2.

In an embodiment, the housing plate HSP may overlap the elastic functional layer EFL in a plan view. In an embodiment, the elastic functional layer EFL may overlap the entire hinge part HG in a plan view. For example, the elastic functional layer EFL may overlap in a plan view with each of the hinge parts located at the central portion of each of the both side surfaces of the housing plate HSP parallel to the first direction DR1.

The structure of the electronic device ED according to embodiments of the present disclosure is not necessarily limited thereto, and a light control film controlling a viewing angle and a light blocking member may be further disposed between the optical functional layer OFL and the cover window WN, or a touch panel sensing a user's touch may be further disposed between the encapsulation layer ENL and the optical functional layer OFL.

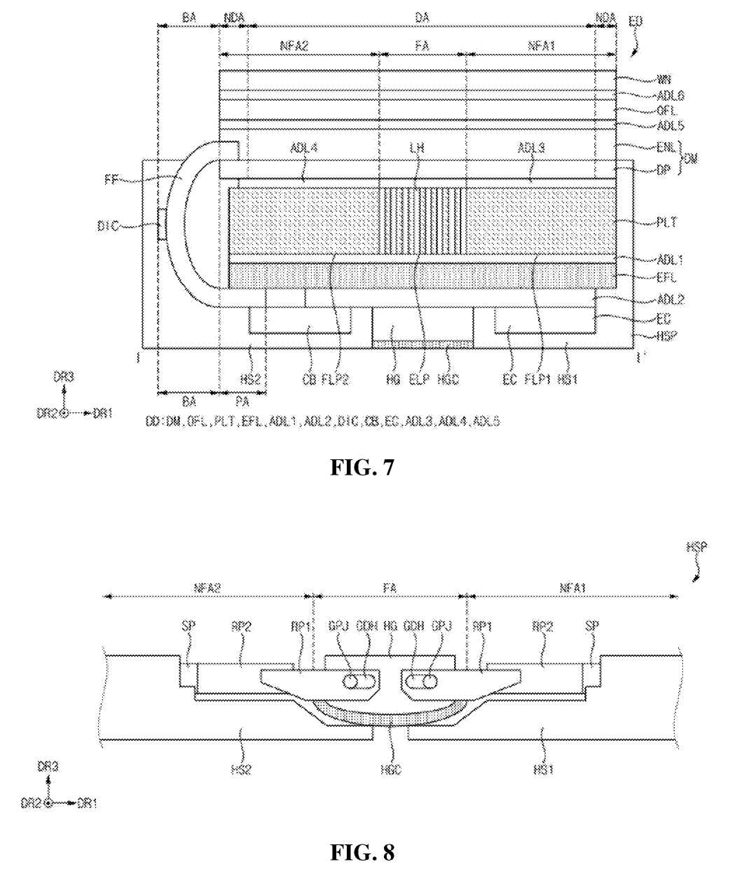

FIG. 7 is a cross-sectional view illustrating another example of a cross-section taken along line I-I' of FIG. 1.

The structure of the electronic device ED described with reference to FIG. 7 may be substantially the same as or similar to the structure of the electronic device ED described with reference to FIG. 6, except that it further includes a flexible circuit film FF. Hereinafter, content overlapping with that described with reference to FIG. 6 may be omitted or briefly described.

Referring to FIGS. 6 and 7, the electronic device ED may further include a flexible circuit film FF.

The substrate SUB included in the display panel DP may be a rigid substrate that is not bent in the bending area BA. In an embodiment, the flexible circuit film FF may be a flexible printed circuit board (FPCB).

The flexible circuit film FF may electrically connect the display panel DP and the circuit board CB to each other. In an embodiment, the flexible circuit film FF may be bent from the second non-folding area NFA2 toward the lower portion of the support plate PLT. The circuit board CB may overlap a portion of the flexible circuit film FF located in the pad area PA in a plan view.

The driving chip DIC may be disposed on the flexible circuit film FF. The driving chip DIC may be electrically connected to the flexible circuit film FF. In other words, the driving chip DIC may have a chip on film (COF) structure. However, the mounting structure of the driving chip DIC according to embodiments of the present disclosure is exemplary and is not necessarily limited thereto.

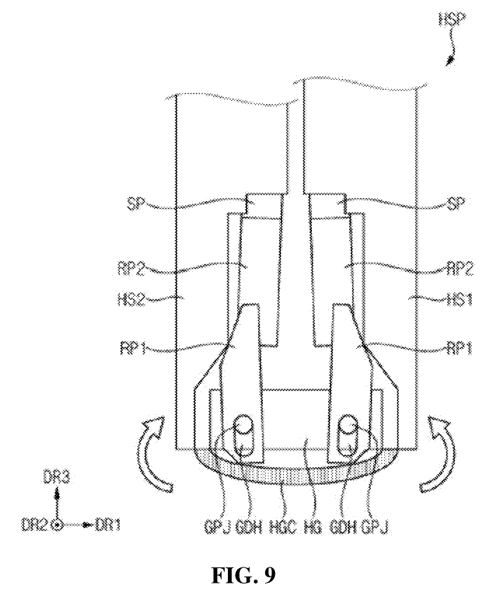

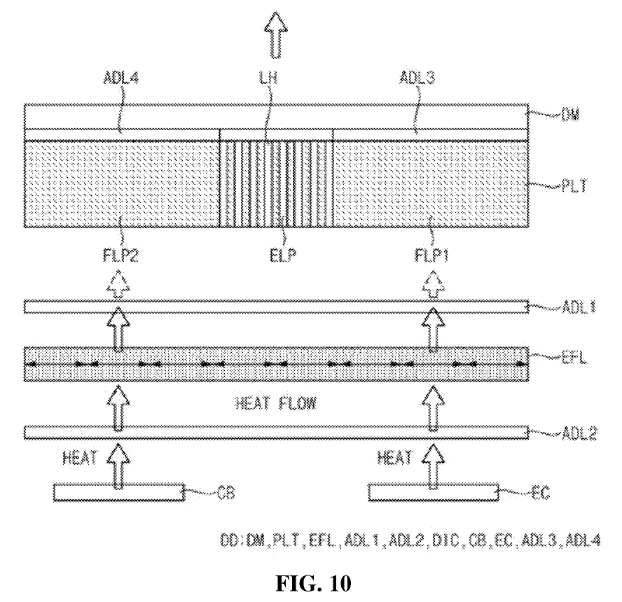

FIG. 8 is a cross-sectional view illustrating a portion of the housing plate of FIG. 4. FIG. 9 is a cross-sectional view illustrating a folded state of the housing plate of FIG. 8. For example, FIG. 8 may be a cross-sectional view illustrating a state in which the housing plate HSP is unfolded.

Referring to FIGS. 8 and 9, the housing plate HSP may include a guide protrusion GPJ, a first rotation plate RP1, a second rotation plate RP2, and a rotation support plate SP. In an embodiment, the guide protrusion GPJ may serve as a rotation axis of the first rotation plate RP1. For example, the guide protrusion GPJ may extend along a direction opposite to the second direction DR2, and the rotation axis may be parallel to the second direction DR2. In an embodiment, the guide protrusion GPJ may be coupled to the hinge part HG.

In an embodiment, one first rotation plate RP1 may be disposed in each of the first non-folding area NFA1 and the second non-folding area NFA2. In an embodiment, a guide groove GDH may be defined in the first rotation plate RP1. The guide groove GDH may be a space for accommodating the guide protrusion GPJ. Accordingly, the guide protrusion GPJ may couple the first rotation plate RP1 and the hinge part HG through the guide groove GDH.

In an embodiment, one second rotation plate RP2 may be disposed in each of the first non-folding area NFA1 and the second non-folding area NFA2. In an embodiment, the second rotation plate RP2 may be coupled to the first rotation plate RP1. Specifically, when the first rotation plate RP1 rotates about the guide protrusion GPJ as the rotation axis as the electronic device ED is folded, the second rotation plate RP2 may also rotate about a portion coupled to the first rotation plate RP1 as a rotation axis.

One rotation support plate SP may be disposed in each of the first non-folding area NFA1 and the second non-folding area NFA2. For example, the rotation support plate SP disposed in the first non-folding area NFA1 may couple the second rotation plate RP2 disposed in the first non-folding area NFA1 and the first housing HS1. Also, the rotation support plate SP disposed in the second non-folding area NFA2 may couple the second rotation plate RP2 disposed in the second non-folding area NFA2 and the second housing HS2. Accordingly, as the electronic device ED is folded, the housing plate HSP may also perform a folding operation.

In a state where the electronic device ED is fully unfolded, the first housing HS1 and the second housing HS2 may cover a portion of the surface of the hinge cover HGC facing outward. In a state where the electronic device ED is fully folded, the hinge cover HGC may be spaced apart from each of the first housing HS1 and the second housing HS2. However, the arrangement relationship of the first housing HS1, the second housing HS2, and the hinge cover HGC according to the operation of the electronic device ED according to embodiments of the present disclosure is not necessarily limited thereto.

FIG. 10 is a diagram for explaining a heat dissipation effect of the electronic device of FIG. 1.

Referring to FIGS. 1, 3, and 10, while the display module DM is driven, heat generated in each of the circuit board CB and the electronic component EC may diffuse toward the display module DM according to a temperature gradient. If heat generated in each of the circuit board CB and the electronic component EC is continuously released to the display module DM, the performance of the display module DM may deteriorate.

As described above, the thermal conductivity of the first adhesive layer ADL1 may be smaller than the thermal conductivity of the second adhesive layer ADL2. Accordingly, heat released from each of the circuit board CB and the electronic component EC may pass through the second adhesive layer ADL2 having a relatively large thermal conductivity and reach the elastic functional layer EFL.

The heat reaching the elastic functional layer EFL easily diffuses in a planar direction parallel to the elastic functional layer EFL, and heat also diffuses in the thickness direction of the elastic functional layer EFL to reach the first adhesive layer ADL1. The heat reaching the first adhesive layer ADL1 does not easily pass through the first adhesive layer ADL1 having a relatively small thermal conductivity, and the transfer of heat toward the display module DM can be reduced.

Accordingly, heat is diffused as much as possible using the elastic functional layer EFL, and heat transferred to the display module DM through the first adhesive layer ADL1 is reduced, so that a heat dissipation effect can be implemented within the electronic device ED. Therefore, since the performance of the display module DM (e.g., the display panel DP) is not deteriorated, the display quality of the display device DD included in the electronic device ED can be improved. Also, the heat durability of the electronic device ED can be improved. That is, an electronic device ED having improved heat dissipation efficiency can be provided.

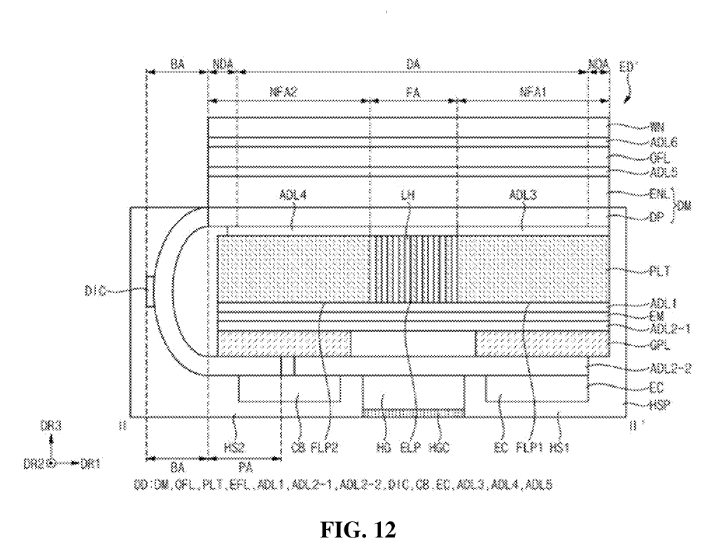

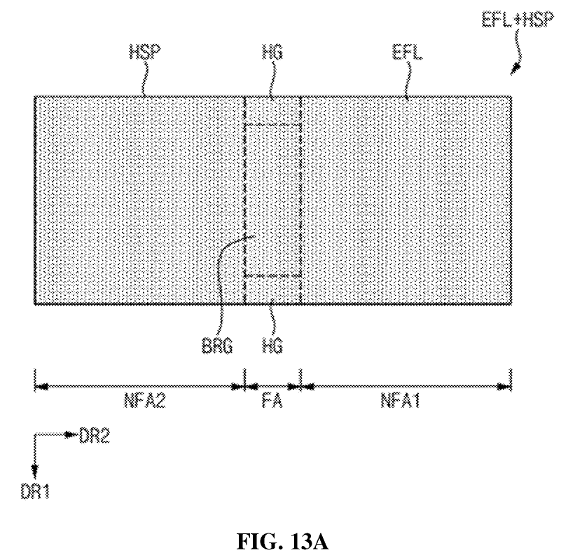

FIG. 11 is an exploded perspective view illustrating a conventional electronic device. FIG. 12 is a cross-sectional view illustrating a cross-section taken along line II-II' of FIG. 11.

The structure of the conventional electronic device ED' described with reference to FIGS. 11 and 12 may be substantially the same as or similar to the electronic device ED described with reference to FIGS. 4 and 5, except that it further includes an elastic member EM and a graphite sheet layer GPL. Hereinafter, content overlapping with that described with reference to FIGS. 4 and 5 may be omitted or briefly described.

Referring to FIGS. 11 and 12, the conventional electronic device ED' includes an elastic member EM and a graphite sheet layer GPL disposed below the support plate PLT. The elastic member EM is a member having a relatively large elastic force or a relatively large restoring force to implement folding and unfolding of the electronic device ED'. The elastic member EM includes thermoplastic polyurethane (TPU).

The graphite sheet layer GPL is a sheet for implementing a heat dissipation function of the electronic device ED'. The graphite sheet layer GPL is coupled to the elastic member EM through a 2-1 adhesive layer ADL2-1. The graphite sheet layer GPL is coupled to each of the circuit board CB and the electronic component EC through a 2-2 adhesive layer ADL2-2.

The graphite sheet layer GPL included in the conventional electronic device ED' does not overlap the hinge part HG in a plan view. In an embodiment, a width (e.g., a length in the first direction DR1) of the graphite sheet layer GPL may decrease from the first non-folding area NFA1 or the second non-folding area NFA2 toward the center of the foldable area FA. For example, the graphite sheet layer GPL may have a planar shape in which chamfering is performed in the foldable area FA so that the width becomes smaller than that in the first non-folding area NFA1 or the second non-folding area NFA2. Specifically, the length of the graphite sheet layer GPL in the first direction DR1 in the foldable area FA may be smaller than the length of the graphite sheet layer GPL in the first direction DR1 in the first non-folding area NFA1 or the second non-folding area NFA2. The elastic member EM and the graphite sheet layer GPL may correspond to the elastic functional layer EFL of FIG. 4.

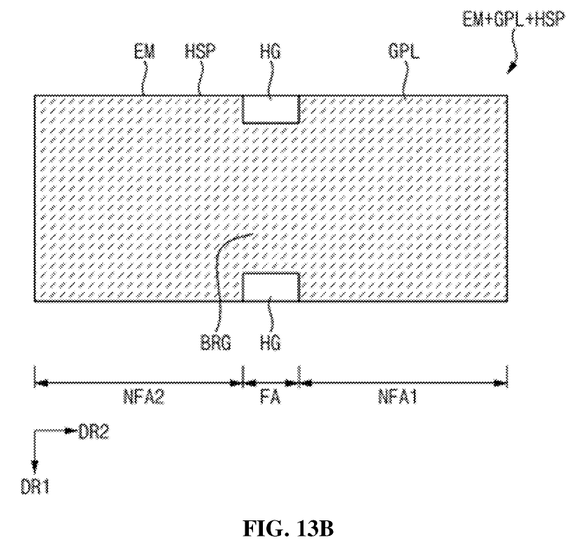

FIG. 13A is a plan view illustrating the electronic device of FIG. 1. FIG. 13B is a plan view illustrating the conventional electronic device of FIG. 11. Referring FIGS. 13A and 13B, the electronic device of FIG. 1 can be compared with the conventional electronic device of FIG. 11. For example, FIG. 13A is a plan view for explaining an overlapping relationship on a plane between the housing plate HSP of FIG. 5 and the elastic functional layer EFL included in the electronic device ED of FIG. 1, and FIG. 13B is a plan view for explaining an overlapping relationship on a plane between the housing plate HSP, the graphite sheet layer GPL, and the elastic member EM included in the conventional electronic device of FIG. 11.

Referring to FIGS. 1, 11, 13A, and FIG. 13B, the elastic functional layer EFL included in the electronic device ED according to an embodiment of the present disclosure may overlap the entire hinge part HG in a plan view. For example, the elastic functional layer EFL may cover the hinge part HG together with the second adhesive layer ADL2. In contrast, the graphite sheet layer GPL included in the conventional electronic device ED' is chamfered in the foldable area FA and does not overlap the hinge part HG in a plan view.

Accordingly, in the electronic device ED according to an embodiment of the present disclosure, since the elastic functional layer EFL overlaps the hinge part HG in a plan view, a process of processing the shape of the graphite sheet layer GPL included in the conventional display device ED' so as not to overlap the hinge part HG may not be additionally required during the manufacturing process of the elastic functional layer EFL. Accordingly, time and cost in the manufacturing process of the display device DD of FIG. 3 and the electronic device ED can be shortened.

In addition, unlike the conventional electronic device ED' which implements a heat dissipation function and an elastic function using two layers, the elastic member EM and the graphite sheet layer GPL, since the heat dissipation function and the elastic function are simultaneously performed by a single layer which is the elastic functional layer EFL, time and cost in the manufacturing process can be further reduced compared to the conventional electronic device ED'.

In addition, the electronic device ED having a thickness thinner than that of the conventional electronic device ED' can be easily manufactured.

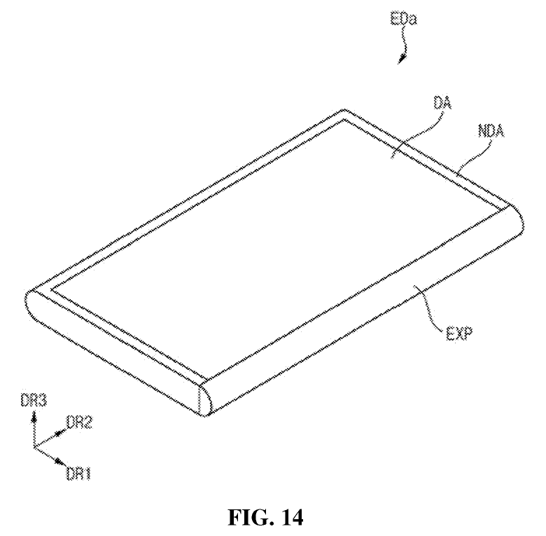

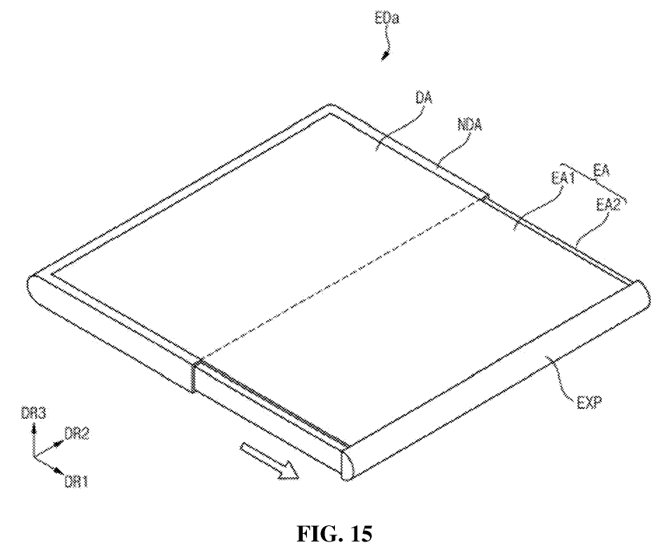

FIG. 14 is a perspective view illustrating an electronic device according to another embodiment of the present disclosure. FIG. 15 is a perspective view illustrating an expanded state of the electronic device of FIG. 14. For example, FIG. 14 is a perspective view illustrating a state before an electronic device EDa according to another embodiment of the present disclosure is expanded.

Referring to FIGS. 14 and 15, the electronic device EDa according to another embodiment of the present disclosure may include a display area DA and a non-display area NDA. Also, the electronic device EDa may include an expansion part EXP. The display area DA may be defined as an area displaying an image, and the non-display area NDA may be defined as an area not displaying an image. The non-display area NDA may surround at least a portion of the display area DA. In an embodiment, the electronic device EDa may be a stretchable electronic device.

The electronic device EDa can be expanded through the expansion part EXP. For example, when a user pulls the expansion part EXP or presses a button for moving the expansion part EXP, the electronic device EDa may expand along the first direction DR1. However, the operation method of the expansion part EXP according to embodiments of the present disclosure is not necessarily limited thereto.

A portion where the electronic device EDa is expanded may define an expansion area EA. A first expansion area EA may correspond to the display area DA. For example, an image may be displayed in the first expansion area EA. A second expansion area EA2 may correspond to the non-display area NDA. For example, an image may not be displayed in the second expansion area EA2.

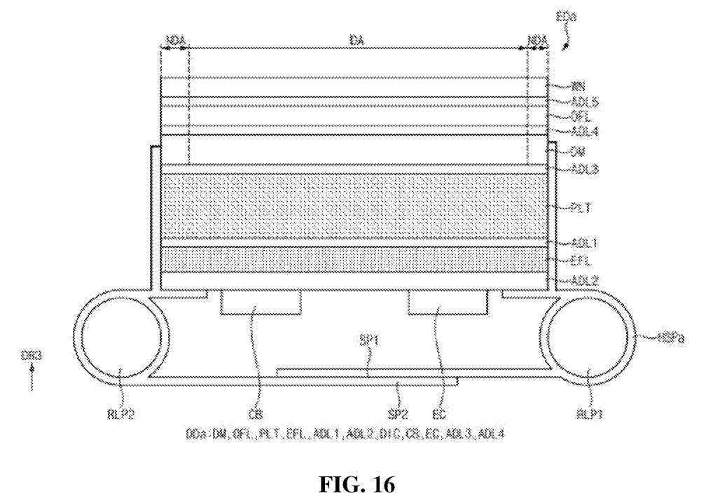

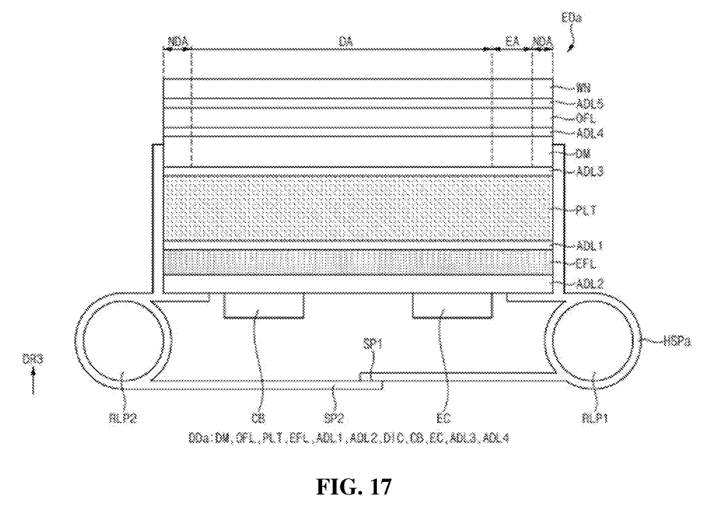

FIG. 16 is a cross-sectional view illustrating a cross-section of the electronic device of FIG. 14. FIG. 17 is a cross-sectional view illustrating a cross-section of the expanded state of the electronic device of FIG. 14. For example, FIG. 16 is a perspective view illustrating a state before the electronic device EDa is expanded.

The electronic device EDa described with reference to FIGS. 16 and 17 may be substantially the same as or similar to the electronic device ED described with reference to FIG. 5, except for the structure of the housing plate HSPa. Hereinafter, content overlapping with that described with reference to FIG. 5 may be omitted or briefly described.

Referring to FIGS. 16 and 17, the electronic device EDa may include a display device DDa and a housing plate HSPa accommodating at least a portion of the display device DDa. The housing plate HSPa may include a first roller part RLP1, a second roller part RLP2, a first support part SP1, and a second support part SP2. The electronic device EDa may be expanded by rotation of the first roller part RLP1 and the second roller part RLP2. For example, as the first roller part RLP1 and the second roller part RLP2 rotate, the first support part SP1 and the second support part SP2 coupled thereto respectively may move away from each other in a plan view. Accordingly, components of the electronic device EDa located in the expansion area EA may extend in the expanded direction.

In an embodiment, the support plate PLT may be coupled to the elastic functional layer EFL through the first adhesive layer ADL1, and the elastic functional layer EFL may be coupled to each of the circuit board CB and the electronic component EC through the second adhesive layer ADL2. In an embodiment, the thermal conductivity of the first adhesive layer ADL1 may be smaller than the thermal conductivity of the second adhesive layer ADL2. In an embodiment, a width (e.g., a width in the first direction DR1 or the second direction DR2 of FIG. 14) of the elastic functional layer EFL may be constant from the non-display area NDA toward a center of the display area DA.

Although FIGS. 16 and 17 do not illustrate a structure in which the driving chip DIC of FIG. 5 is mounted, a structure in which a driving chip is mounted on a display panel included in the display module DM of the electronic device EDa may be substantially the same as or similar to the structure of the electronic device ED of FIG. 5 or 6.

As described above, in the electronic device EDa according to embodiments of the present disclosure, the thermal conductivity of the first adhesive layer ADL1 coupling the support plate PLT and the elastic functional layer EFL to each other may be smaller than the thermal conductivity of the second adhesive layer ADL2 coupling the elastic functional layer EFL and the circuit board CB/electronic component EC to each other. Accordingly, heat emitted from each of the circuit board CB and the electronic component EC and transferred to the display panel DP can be effectively reduced. Therefore, the electronic device EDa having improved heat dissipation efficiency and improved display quality can be provided.

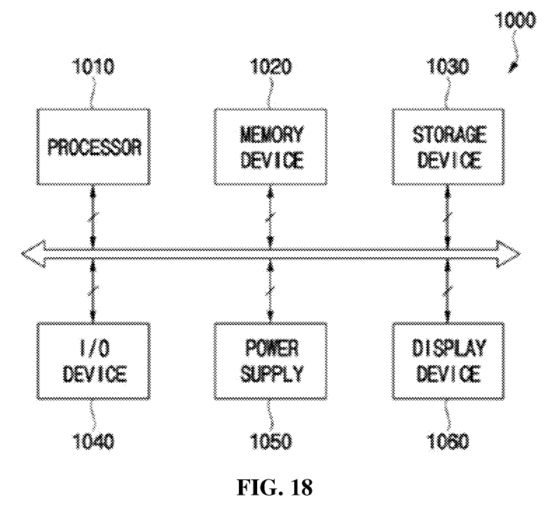

FIG. 18 is a block diagram illustrating the electronic devices of FIGS. 1 and 14.

Referring to FIG. 18, an electronic device 1000 may include a processor 1010, a memory device 1020, a storage device 1030, an input/output device 1040, a power supply 1050, and a display device 1060. The electronic device 1000 may be the electronic devices ED and EDa of FIGS. 1 and 14. When the electronic device 1000 includes the display device 1060, the display device 1060 may be the display devices DD and DDa of FIGS. 4 and 16. Also, the electronic device 1000 may further include several ports capable of communicating with a video card, a sound card, a memory card, a USB device, etc., or communicating with other systems.

In an embodiment, the electronic device 1000 may be implemented as a smartphone. However, the type of the electronic device 1000 according to embodiments of the present disclosure is exemplary, and the type of the electronic device 1000 is not necessarily limited thereto. For example, the electronic device 1000 may be implemented as a mobile phone, a video phone, a smart pad, a smart watch, a tablet PC, a vehicle navigation system, a computer monitor, a laptop, a head mounted display device, and the like. Also, the electronic device 1000 may be various types of flexible electronic devices in addition to the aforementioned foldable electronic device and stretchable electronic device.

In an embodiment, the processor 1010 may be a microprocessor, a central processing unit, an application processor, or the like. The processor 1010 may be connected to other components through an address bus, a control bus, a data bus, and the like. According to an embodiment, the processor 1010 may also be connected to an expansion bus such as a Peripheral Component Interconnect (PCI) bus.

In an embodiment, the processor 1010 may output the input image data IMG and the input control signal CONT to the driving controller 200 of FIG. 1.

In an embodiment, the memory device 1020 may store data necessary for the operation of the electronic device 1000. For example, the memory device 1020 may include non-volatile memory devices such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM), a Ferroelectric Random Access Memory (FRAM) device, etc., and/or volatile memory devices such as a Dynamic Random Access Memory (DRAM) device, a Static Random Access Memory (SRAM) device, a mobile DRAM device, etc.

In an embodiment, the storage device 1030 may include a Solid State Drive (SSD), a Hard Disk Drive (HDD), a CD-ROM, and the like.

In an embodiment, the input/output device 1040 may include input means such as a keyboard, a keypad, a touchpad, a touchscreen, a mouse, etc., and output means such as a speaker, a printer, etc.

In an embodiment, the display device 1060 may be included in the input/output device 1040. However, the relationship between the input/output device 1040 and the display device 1060 according to embodiments of the present disclosure is not necessarily limited thereto. In an embodiment, the power supply 1050 may supply power necessary for the operation of the electronic device 1000. In an embodiment, the display device 1060 may be connected to other components through the buses or other communication links.

The present disclosure may be applied to a display device and an electronic device including the same. For example, the present disclosure may be applied to a high-resolution smartphone, a mobile phone, a smart pad, a smart watch, a tablet PC, a vehicle navigation system, a television, a computer monitor, a laptop, and the like.

Although the present disclosure has been described with reference to exemplary embodiments, those skilled in the art will understand that various modifications and changes can be made to the present disclosure without departing from the spirit and scope of the present disclosure described in the following claims.

What is claimed is:

1. A display device, comprising:
an elastic functional layer comprising an elastic material and a thermally conductive material;
a support plate disposed over the elastic functional layer;
a display panel disposed over the support plate and comprising a plurality of pixels;
a circuit board disposed below the elastic functional layer and electrically connected to the display panel;
a first adhesive layer disposed between the display panel and the support plate in a cross-sectional view to couple the display panel and the support plate to each other; and
a second adhesive layer disposed between the elastic functional layer and the circuit board in a cross-sectional view to couple the elastic functional layer and the circuit board to each other, the second adhesive layer having a thermal conductivity greater than a thermal conductivity of the first adhesive layer.

2. The display device of claim 1, wherein the thermally conductive material comprises at least one selected from the group consisting of graphite powder, graphene, carbon fiber, carbon nano tube, and boron nitride (BN).

3. The display device of claim 2, wherein the elastic material comprises at least one selected from the group consisting of silicon (Si), polyurethane (PU), thermoplastic polyurethane (TPU), and polydimethylacrylamide (PDMA).

4. The display device of claim 1, wherein a weight ratio of the thermally conductive material included in the elastic functional layer is 50 wt% or less.

5. The display device of claim 1, wherein a thickness of the elastic functional layer is in a range of 10 μm to 300 μm.

6. The display device of claim 1, wherein a thermal conductivity of the elastic functional layer is in a range of 5 W/(m·K) to 40 W/(m·K).

7. The display device of claim 1, wherein the display panel comprises a foldable area and a non-folding area adjacent to the foldable area, and
wherein a width of the elastic functional layer is constant from the non-folding area toward a center of the foldable area.

8. The display device of claim 7, wherein the support plate comprises a stretchable part disposed in the foldable area and a flat part disposed in the non-folding area, and
wherein a plurality of lattice holes passing through the support plate in a thickness direction are defined in the stretchable part.

9. The display device of claim 8, wherein the elastic functional layer overlaps the entire stretchable part in a plan view.

10. An electronic device, comprising:
a display panel including a foldable area and a non-folding area adjacent to the foldable area, the display panel comprising a plurality of pixels;
an elastic functional layer disposed in the foldable area and the non-folding area under the display panel, the elastic functional layer comprising an elastic material and a thermally conductive material;
a support plate disposed in the foldable area and the non-folding area on the elastic functional layer;
a circuit board disposed in the non-folding area under the elastic functional layer and electrically connected to the display panel;
a first adhesive layer disposed between the display panel and the support plate in a cross-sectional view to couple the display panel and the support plate to each other;
a second adhesive layer disposed between the elastic functional layer and the circuit board in a cross-sectional view to couple the elastic functional layer and the circuit board to each other, the second adhesive layer having a thermal conductivity greater than a thermal conductivity of the first adhesive layer; and
a housing plate providing a space accommodating the display panel, the elastic functional layer, the support plate, and the circuit board.

11. The electronic device of claim 10, wherein the thermally conductive material comprises at least one selected from the group consisting of graphite powder, graphene, carbon fiber, carbon nano tube, and boron nitride (BN).

12. The electronic device of claim 11, wherein the elastic material comprises at least one selected from the group consisting of silicon (Si), polyurethane (PU), thermoplastic polyurethane (TPU), and polydimethylacrylamide (PDMA).

13. The electronic device of claim 10, wherein a weight ratio of the thermally conductive material included in the elastic functional layer is 50 wt% or less.

14. The electronic device of claim 10, wherein a thickness of the elastic functional layer is in a range of 10 μm to 300 μm.

15. The electronic device of claim 10, wherein a thermal conductivity of the elastic functional layer is in a range of 5 W/(m·K) to 40 W/(m·K).

16. The electronic device of claim 10, wherein the housing plate comprises:
a housing disposed in the non-folding area and accommodating the circuit board; and
a hinge part disposed in the foldable area and protruding from one side surface of the housing plate toward an inside of the housing plate.

17. The electronic device of claim 16, wherein the elastic functional layer overlaps the entire hinge part in a plan view.

18. The electronic device of claim 10, wherein a width of the elastic functional layer is constant from the non-folding area toward a center of the foldable area.

19. The electronic device of claim 10, further comprising a battery module disposed in the non-folding area under the elastic functional layer and supplying power to the display panel,
wherein the second adhesive layer couples the battery module and the elastic functional layer to each other.

20. An electronic device comprising:
a display panel comprising a plurality of pixels, the display panel including a foldable area and a non-folding area adjacent to the foldable area;
an elastic functional layer disposed in the foldable area and the non-folding area under the display panel, the elastic functional layer comprising an elastic material and a thermally conductive material;
a support plate disposed in the foldable area and the non-folding area on the elastic functional layer;
a circuit board disposed in the non-folding area under the elastic functional layer and electrically connected to the display panel; and
a housing plate comprising a housing disposed in the non-folding area and accommodating the circuit board, and a hinge part disposed in the foldable area,
wherein the elastic functional layer overlaps the entire hinge part in a plan view, and
wherein a width of the elastic functional layer is constant from the non-folding area toward a center of the foldable area.
